(19) United States
(12) Patent Application Publication
(10) Pub. No.: US 2012/0140429 A1
(43) Pub. Date: Jun. 7, 2012

(54) DISPLAY DEVICE

(75) Inventor: Katsumasa Tanaka, Kanagawa (JP)

(73) Assignee: SONY CORPORATION, Tokyo (JP)

(21) Appl. No.: 13/300,856

(22) Filed: Nov. 21, 2011

(30) Foreign Application Priority Data
Dec. 3, 2010 (JP) P2010-270785

(51) Int. Cl. H05K 7/02

(52) U.S. Cl. 361/807

(57) ABSTRACT

A display device includes a display which has a display surface which displays an image and where a lower edge portion is provided as a contact portion, a holding member which is placed on a placement surface, contacts the contact portion of the display from above, and holds the display, and a stand where an upper edge portion is provided as a upper-side attachment portion which is attached to the display and a lower edge portion is provided as a lower-side attachment portion which is attached to the holding member, where it is possible to change the inclination angle of the display in the tilt direction to a plurality of angles which are different and a position of the contact portion of the display, which contacts with the holding member, and the lower-side attachment portion of the stand are positioned so as to be separated back and front.

### BACKGROUND

The present disclosure relates to a technical field with regard to display devices. In detail, the present disclosure relates to a technical field of achieving stability of a holding state of a display irrespective of an inclination angle by positioning a position on a lower surface of a display, which contacts with a holding member, and a lower-side attachment portion of a stand where the holding member is attached so as to be separated back and front in a configuration where it is possible to change the inclination angle of the display in a tilt direction.

In a display device such as a television reception device, there is a type where a display is held using a stand and a holding member. In this type of display device, for example, a lower edge portion of the stand is attached to the holding member which is placed on a placement surface and the upper edge portion of the stand is attached to the rear surface of the display (for example, Japanese Unexamined Patent Application Publication No. 2009-58916).

Accordingly, the display is held by the holding member and the stand in a state of being positioned above the holding member.

### SUMMARY

However, in the display device which is described in Japanese Unexamined Patent Application Publication No. 2009-58916, since the display is held in a state of being positioned above the holding member, a portion which is a supporting point for holding the display in the holding member is one location of a portion where the lower edge portion of the stand and the holding member are joined.

Accordingly, the holding state of the display is unstable and there is a concern that the display may shake and there may be distortion of an image displayed on a display surface and that the burden applied to the stand is large and the stand may become deformed.

In addition, as the display device, there is a type where it is possible to change the inclination angle of the display in the tilt direction and it is possible to hold the display at a desired inclination angle and set the image displayed on the display surface to an angle which is easy to view.

Even with this type, it is necessary to secure the stable holding state of the display irrespective of the inclination angle of the display in the tilt direction and prevent a defect from occurring such as image distortion.

Therefore, it is desirable to achieve stability of a holding state of a display irrespective of the inclination angle.

A display device according to an embodiment of the present disclosure is provided with a display which has a display surface which displays an image and where a lower edge portion is provided as a contact portion, a holding member which is placed on a placement surface, contacts the contact portion of the display from above, and holds the display, and a stand where an upper edge portion is provided as a upper-side attachment portion which is attached to the display and a lower edge portion is provided as a lower-side attachment portion which is attached to the holding member, where it is possible to change the inclination angle of the display in the tilt direction with regard to the stand to a plurality of angles which are different and a position of the contact portion of the display, which contacts with the holding member, and the lower-side attachment portion of the stand are positioned so as to be separated back and front.

Accordingly, in the display device, the position of the lower surface of the display, which contacts with the holding member, and the lower-side attachment portion of the stand function as a supporting point which supports the display irrespective of the inclination angle of the display in the tilt direction.

In the display device described above, it is desirable that a base plate which has the upper-side attachment portion, a support base which has the lower-side attachment portion, and an angle changing base which is connected to the base plate and the support base are provided in the stand, a plurality of types of joining portions where the orientation in the tilt direction is different is provided in the angle changing base, and the inclination angle of the display in the tilt direction is changed by the plurality of joining portions being selectively joined with the base plate.

By the inclination angle of the display in the tilt direction being changed by the plurality of joining portions being selectively joined with the base plate, the inclination angle of the display in the tilt direction is changed by changing the position of the angle changing base which joins with the base plate.

In the display device described above, it is desirable that a first joining portion and a second joining portion are provided as the joining portions.

By the first joining portion and the second joining portion being provided as the joining portions, the inclination angle of the display in the tilt direction is changed by changing the position which joins with the base plate to the first joining portion or the second joining portion.

In the display device described above, it is desirable that the base plate is connected to the angle changing base so as to be able to rotate in the tilt direction.

By the base plate being connected to the angle changing base so as to be able to rotate in the tilt direction, the base plate is rotated in regard to the angle changing base when changing the inclination angle of the display in the tilt direction.

In the display device described above, it is desirable that a connecting protrusion portion which has a support hole is provided in the base plate, a connecting portion which has an insertion hole is provided in the angle changing base, the base plate is connected to the angle changing base so as to be able to rotate in the tilt direction by a rotation shaft which extends in a horizontal direction being inserted in the support hole and the insertion hole, the insertion hole is formed in an elongated shape which extends up and down, and a position with regard to the insertion hole of the rotation shaft is changed in the up and down direction and the base plate and the display are integrated and move in the up and down direction when the types of the joining portions which are joined to the base plate are changed.

By the position with regard to the insertion hole of the rotation shaft being changed in the up and down direction and the base plate and the display being integrated and moving in the up and down direction when the types of the joining portions which are joined to the base plate are changed, the display moves in the up and down direction when changing the inclination angle of the display.

In the display device described above, it is desirable that a member with a shaft shape, which is formed from a base portion which extends left and right and a pair of side portions which respectively extend forward from both left and right edge portions of the base portion, is provided as the holding member and the lower-side attachment portion of the stand is attached to the center portion of the base portion in the left and right direction.

By the lower-side attachment portion of the stand being attached to the center portion of the base portion in the left and right direction, excellent balance of the stand is secured with regard to the holding member.

In the display device described above, it is desirable that the contact portion of the display contacts with the holding member in two locations.

By the contact portion of the display contacting with the holding member in two locations, along with the lower-side attachment portion of the stand, the display is supported at three locations.

In the display device described above, it is desirable that the positions of the contact portion of the display which contacts with the holding member are positioned so as to be separated in the left and right direction.

By the position of the contact portion of the display, which contacts with the holding member, being positioned so as to be separated in the left and right direction, along with the lower-side attachment portion, the display is supported at three locations which formed corners of a triangle.

In the display device described above, it is desirable that the inclination angle of the display in the tilt direction is set as 0° where the display surface faces the front or another angle where the display surface faces upward of the front.

By the inclination angle of the display in the tilt direction being set as 0° where the display surface faces the front or another angle where the display surface faces upward of the front, visibility of an image which is displayed on the display surface is improved at any inclination angle.

In the display device described above, it is desirable that the display is able to rotate in the horizontal direction.

By the display being able to rotate in the horizontal direction, the display is able to rotate to a position where the visibility of the image which is displayed on the display surface is high.

In the display device described above, it is desirable that the angle changing base is supported by the support base so as to rotate freely in the horizontal direction.

By the angle changing base being supported by the support base so as to rotate freely in the horizontal direction, the changing of the inclination angle in the tilt direction and the rotation in the horizontal direction of the display are performed by the angle changing base which is the same part.

In the display device described above, it is desirable that a sliding plate, which is formed between the angle changing base and the support base from a resin material, is disposed, and the angle changing base and the sliding plate are integrated and rotate with regard to the support base when the display is rotated in the horizontal direction.

By the angle changing base and the sliding plate being integrated and rotating with regard to the support base when the display is rotated in the horizontal direction, the sliding plate which is formed from the resin material slides with the support base.

In the display device described above, it is desirable that a rotating plate, which is disposed in a state of being in contact with the support base at a side opposite to the angle changing base so the support base is interposed, is provided and the angle changing base and the rotating plate are joined using a screw member at a rotation supporting point while interposing the support base.

By the angle changing base and the rotating plate being joined using a screw member at a rotation supporting point while interposing the support base, a rotating mechanism is configured which rotates the display in the horizontal direction by the angle changing base and the rotating plate being joined using the screw member at a rotation supporting point.

In the display device described above, it is desirable that a sliding plate, which is formed between the angle changing base and the support base from a resin material, is disposed, the rotating plate is formed from a resin material, and the angle changing base, the sliding plate, and the rotating plate are integrated and rotate with regard to the support base when the display is rotated in the horizontal direction.

By the rotating plate being formed from the resin material and the angle changing base, the sliding plate, and the rotating plate being integrated and rotating with regard to the support base when the display is rotated in the horizontal direction, the sliding plate and the rotating plate slide with the support base.

In the display device described above, it is desirable that a cover body, which covers the base plate and the angle changing base, is provided.

By providing a cover body which covers the base plate and the angle changing base, the amount of dust which enters inside of the cover body is reduced.

In the display device described above, it is desirable that the plurality of joining portions are selectively joined up with the base plate using a changing attaching screw, a cover body, which covers the base plate and the angle changing base, is provided, and a screw fastening hole is formed so that it is possible for the changing attaching screw to be inserted in or removed from the cover body.

By providing a cover body which covers the base plate and the angle changing base and a screw fastening hole being formed so that it is possible for the changing attaching screw to be inserted in or removed from the cover body, it is possible to change the position of the angle changing base which joins with the base plate in a state where the base plate and the angle changing base are covered by the cover body.

The display device according to the embodiment of the disclosure is provided with a display which has a display surface which displays an image and where a lower edge portion is provided as a contact portion, a holding member which is placed on a placement surface, contacts the contact portion of the display from above, and holds the display, and a stand where an upper edge portion is provided as a upper-side attachment portion which is attached to the display and a lower edge portion is provided as a lower-side attachment portion which is attached to the holding member, where it is possible to change the inclination angle of the display in the tilt direction with regard to the stand to a plurality of angles which are different and a position of the contact portion of the display, which contacts with the holding member, and the lower-side attachment portion of the stand are positioned so as to be separated back and front.

Accordingly, the position of the contact portion of the display, which contacts with the holding member, and the lower-side attachment portion of the stand are positioned so as to be separated back and front and normally function as a supporting point which supports the display, and it is possible to achieve stability of the holding state of the display irrespective of the inclination angle of the display.

In the display device according to the embodiment of the disclosure, a base plate which has the upper-side attachment portion, a support base which has the lower-side attachment portion, and an angle changing base which is connected to the base plate and the support base may be provided in the stand, a plurality of types of joining portions where the orientations in the tilt direction are different may be provided in the angle changing base, and the inclination angle of the display in the tilt direction may be changed by the plurality of joining portions being selectively joined with the base plate.

Accordingly, since the inclination angle of the display in the tilt direction is changed by only changing the position of the angle changing base which joins with the base plate, it is possible to easily perform the changing of the inclination angle of the display.

In the display device according to the embodiment of the disclosure, a first joining portion and a second joining portion may be provided as the joining portions.

Accordingly, since the inclination angle of the display in the tilt direction is changed by only changing the position which joins with the base plate of the angle changing base to the first joining portion or the second joining portion, it is possible to easily performing the changing of the inclination angle of the display.

In the display device according to the embodiment of the disclosure, the base plate may be connected to the angle changing base so as to be able to rotate in the tilt direction.

Accordingly, it is possible to easily and promptly perform the changing of the inclination angle of the display without the joining of the base plate and the angle changing base being released when changing the inclination angle of the display in the tilt direction.

In the display device according to the embodiment of the disclosure, a connecting protrusion portion which has a support hole may be provided in the base plate, a connecting portion which has an insertion hole may be provided in the angle changing base, the base plate may be connected to the angle changing base so as to be able to rotate in the tilt direction by a rotation shaft which extends in a horizontal direction being inserted in the support hole and the insertion hole, the insertion hole may be formed in an elongated shape which extends up and down, and a position with regard to the insertion hole of the rotation shaft may be changed in the up and down direction and the base plate and the display may be integrated and move in the up and down direction when the types of the joining portions which are joined to the base plate are changed.

Accordingly, since the base plate and the display moves in the up and down direction with the rotation shaft when changing the inclination angle of the display, it is possible to reliably contact the contact portion of the display with the holding member irrespective of the inclination angle of the display.

In the display device according to the embodiment of the disclosure, a member with a shaft shape, which is formed from a base portion which extends left and right and a pair of side portions which respectively extend forward from both left and right edge portions of the base portion, may be provided as the holding member and the lower-side attachment portion of the stand may be attached to the center portion of the base portion in the left and right direction.

Accordingly, it is possible to achieve stability of the holding state of the display.

In the display device according to the embodiment of the disclosure, the contact portion of the display may contact with the holding member in two locations.

Accordingly, since along with the lower-side attachment portion of the stand, the display is supported at three locations, it is possible to achieve further stability of the holding state of the display.

In the display device according to the embodiment of the disclosure, the positions of the contact portion of the display, which contacts with the holding member, may be positioned so as to be separated in the left and right direction.

Accordingly, along with the lower-side attachment portion, the display is supported at three locations which formed corners of a triangle, and it is possible to achieve further stability of the holding state of the display.

In the display device according to the embodiment of the disclosure, the inclination angle of the display in the tilt direction may be set as 0° where the display surface faces the front or another angle where the display surface faces upward of the front.

Accordingly, it is possible to select and view at an angle where visibility of an image which is displayed on the display surface is high.

In the display device according to the embodiment of the disclosure, the display may be made to be able to rotate in the horizontal direction.

Accordingly, it is possible to select and view at an angle where visibility of an image which is displayed on the display surface is high.

In the display device according to the embodiment of the disclosure, the angle changing base may be supported by the support base so as to rotate freely in the horizontal direction.

Accordingly, the changing of the inclination angle in the tilt direction and the rotation in the horizontal direction of the display is performed by the angle changing base which is the same part, and it is possible to achieve a reduction in the number of parts and a simplified structure.

In the display device according to the embodiment of the disclosure, a sliding plate, which is formed between the angle changing base and the support base from a resin material, may be disposed, and the angle changing base and the sliding plate may be integrated and rotate with regard to the support base when the display is rotated in the horizontal direction.

Accordingly, since the sliding plate which is formed from the resin material slides with the support base, it is possible to secure excellent slidability of the sliding plate with regard to the support base and to rotate the display smoothly in the horizontal direction.

In the display device according to the embodiment of the disclosure, a rotating plate, which is disposed in a state of being in contact with the support base at a side opposite to the angle changing base so the support base is interposed, may be provided and the angle changing base and the rotating plate may be joined using a screw member at a rotation supporting point while interposing the support base.

Accordingly, since a rotating mechanism is configured which rotates the display in the horizontal direction by the angle changing base and the rotating plate being joined using a screw member at a rotation supporting point, it is possible to achieve a reduction in the number of parts and a simplified configuration using the rotation mechanism.

In the display device according to the embodiment of the disclosure, a sliding plate, which is formed between the angle changing base and the support base from a resin material, may be disposed, the rotating plate may be formed from a resin material, and the angle changing base, the sliding plate, and the rotating plate may be integrated and rotate with regard to the support base when the display is rotated in the horizontal direction.

Accordingly, it is possible to secure excellent slidability of the sliding plate and the rotation plate with regard to the support base and to rotate the display more smoothly in the horizontal direction.

In the display device according to the embodiment of the disclosure, a cover body, which covers the base plate and the angle changing base, may be provided.

Accordingly, it is possible to prevent dust from adhering to the base plate and the angle changing base.

In the display device according to the embodiment of the disclosure, the plurality of joining portions may be selectively joined up with the base plate using a changing attaching screw, a cover body, which covers the base plate and the angle changing base, may be provided, and a screw fastening hole may be formed so that it is possible for the changing attaching screw to be inserted in or removed from the cover body.

Accordingly, it is possible to perform the changing of the position of the joining without removing the cover body from the display and it is possible to easily and promptly perform the changing of the position of the angle changing base which joins with the base plate.

### BRIEF DESCRIPTION OF THE DRAWINGS

FIG. 1 is a perspective diagram of a display device according to an embodiment of the present disclosure along with FIGS. 2 to 20;

FIG. 2 is a perspective diagram illustrating a rear surface side of the display device;

FIG. 3 is an exploded perspective diagram of the display device;

FIG. 4 is an exploded perspective diagram illustrating a stand and a holding member of the display device;

FIG. 5 is an enlarged perspective diagram illustrating a state where the stand is attached to the display and the holding member;

FIG. 6 is an enlarged exploded perspective diagram illustrating a base plate and an angle changing base;

FIG. 7 is an enlarged cross-sectional diagram of the angle changing base;

FIG. 8 is an enlarged cross-sectional diagram illustrating a state where a first joining portion of the angle changing base is joined to the base plate and the base plate is held in a first rotation position;

FIG. 9 is an enlarged cross-sectional diagram illustrating a state where a second joining portion of the angle changing base is joined to the base plate and the base plate is held in a second rotation position;

FIG. 10 is an enlarged perspective diagram of a cover body;

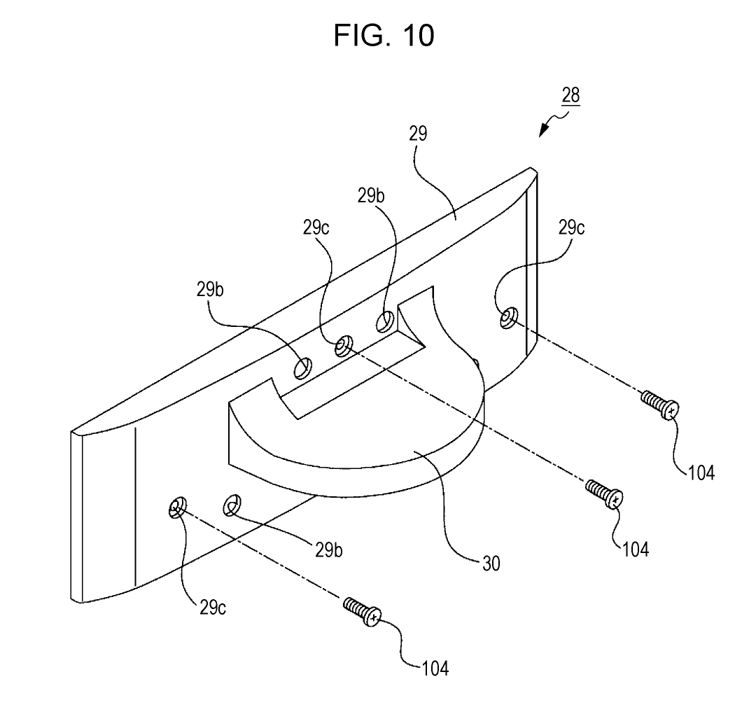

FIG. 11 is an enlarged cross-sectional diagram illustrating a state where the base plate and the angle changing base are covered by the cover body;

FIG. 12 is an enlarged exploded perspective diagram illustrating a state where the first joining portion of the angle changing base is joined to the base plate;

FIG. 13 is an enlarged cross-sectional diagram illustrating a state where the first joining portion of the angle changing base has been joined to the base plate;

FIG. 14 is a side view illustrating a state where a display is held in an inclined state;

FIG. 15 is an enlarged exploded perspective diagram illustrating a state where the second joining portion of the angle changing base is joined to the base plate;

FIG. 16 is an enlarged cross-sectional diagram illustrating a state where the second joining portion of the angle changing base has been joined to the base plate;

FIG. 17 is a side view illustrating a state where the display is held in a horizontal state;

FIG. 18 is a perspective diagram illustrating a state where changing of a position of the angle changing base, which contacts with the base plate, is performed in a state where the base plate and the angle changing base are covered by the cover body;

FIG. 19 is a perspective diagram illustrating a state where the display is rotated in one direction in the horizontal direction; and

FIG. 20 is a perspective diagram illustrating a state where the display is rotated in the other direction in the horizontal direction.

### DETAILED DESCRIPTION OF EMBODIMENTS

Below, an embodiment of the disclosure will be described in accordance with the attached diagrams.

The embodiment shown below is an application of a display device of the disclosure as a television reception device. Here, the application range of the disclosure is not limited to a television reception device, and for example, it is possible for the disclosure to be widely applied to various types of display devices which have a display which displays an image such as a personal computer or an electronic photo frame.

### [Configuration of Display Device]

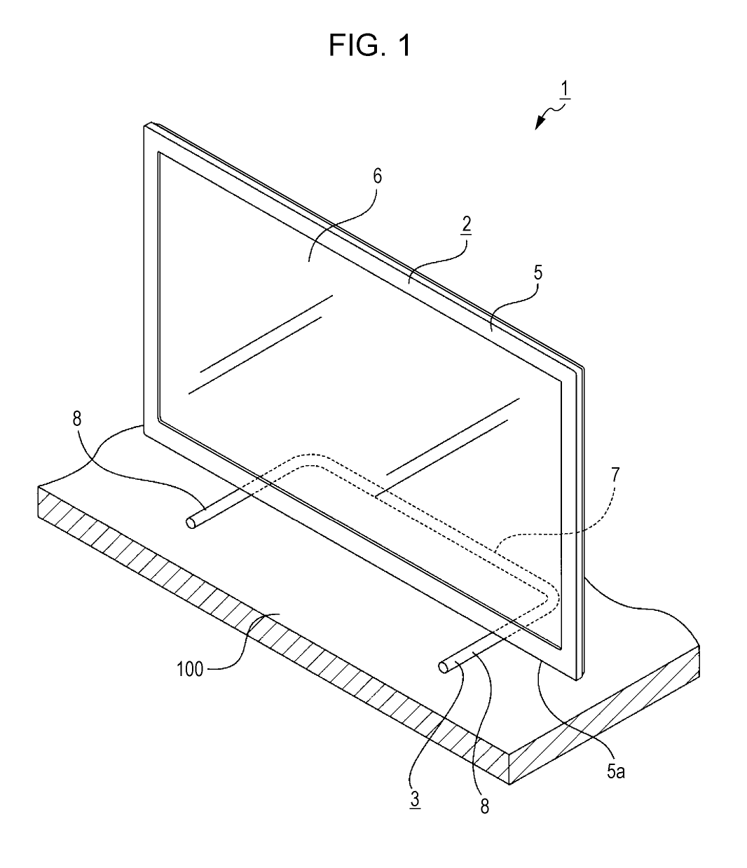

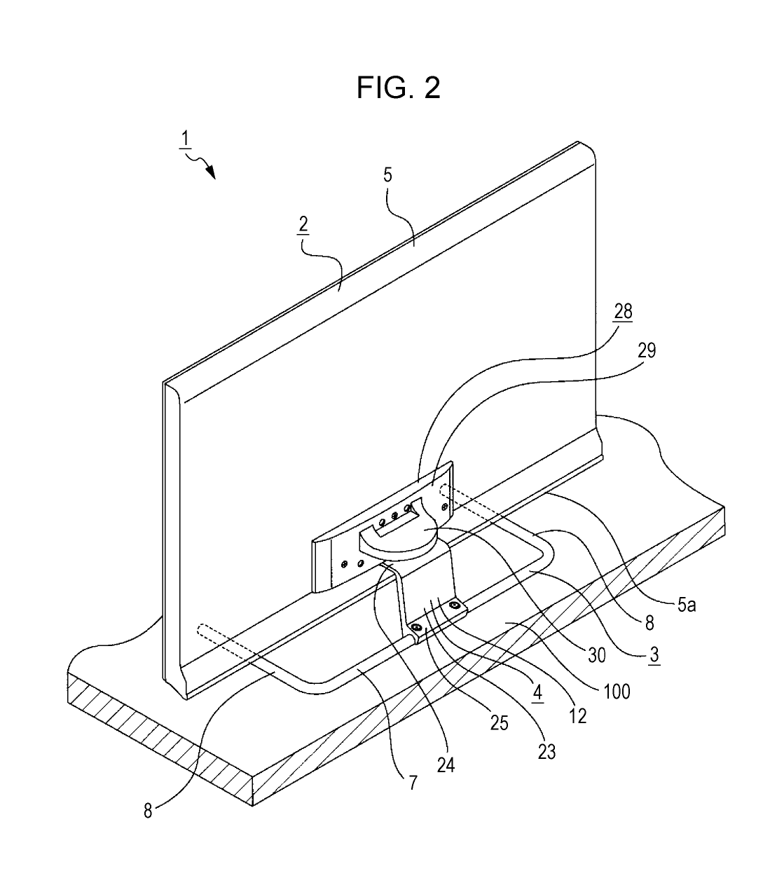

A display device 1 is provided with a display 2 which displays an image, a holding member 3 which is placed on a placement surface 100 such as a platform or the floor, and a stand 4 which holds the display 2 at a predetermined angle as shown in FIGS. 1 and 2.

The display 2 has a housing 5 which is formed, for example, in a flattened rectangular shape from front to back in a lateral length and a display surface 6 which faces forward so as to display an image. A lower edge portion of the housing 5 is provided as a contact portion 5a where the thickness is thicker than other portions. In the lower surface of the contact portion 5a, a contact surface portion (not shown), which is formed using a resin material or the like which has excellent slidability, is provided.

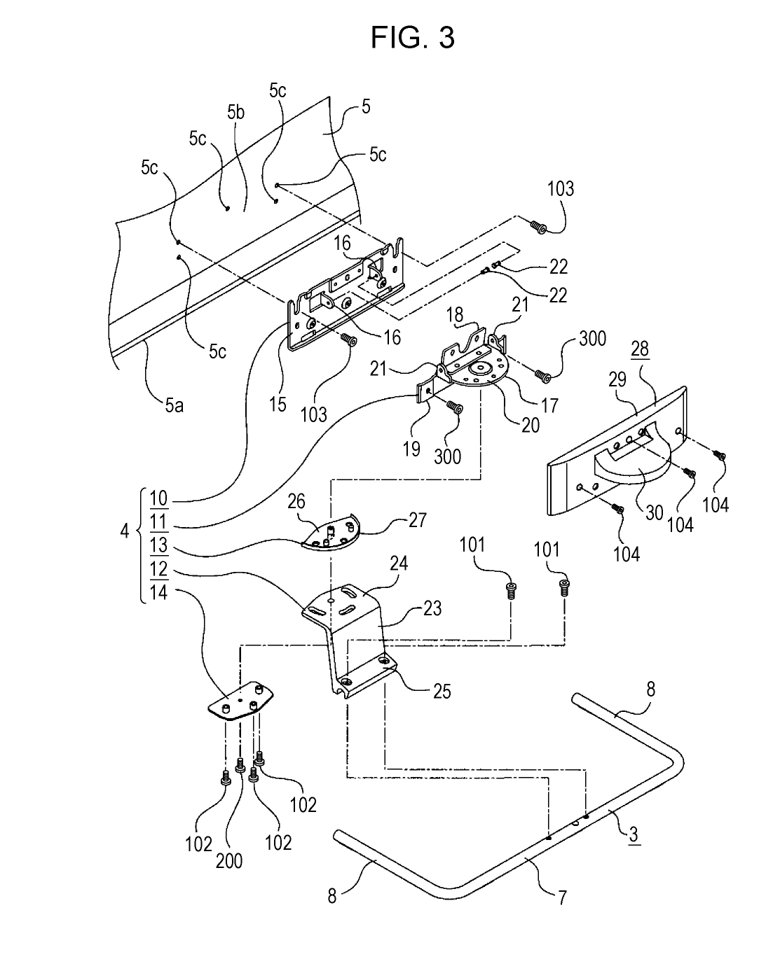

In the rear surface of the housing 5, a portion toward the lower edge in the center portion in the left and right direction is formed as an attaching portion 5b (refer to FIG. 3). In the attaching portion 5b, a plurality of screw fastening holes 5c, 5c, . . . which are opened to the rear is formed.

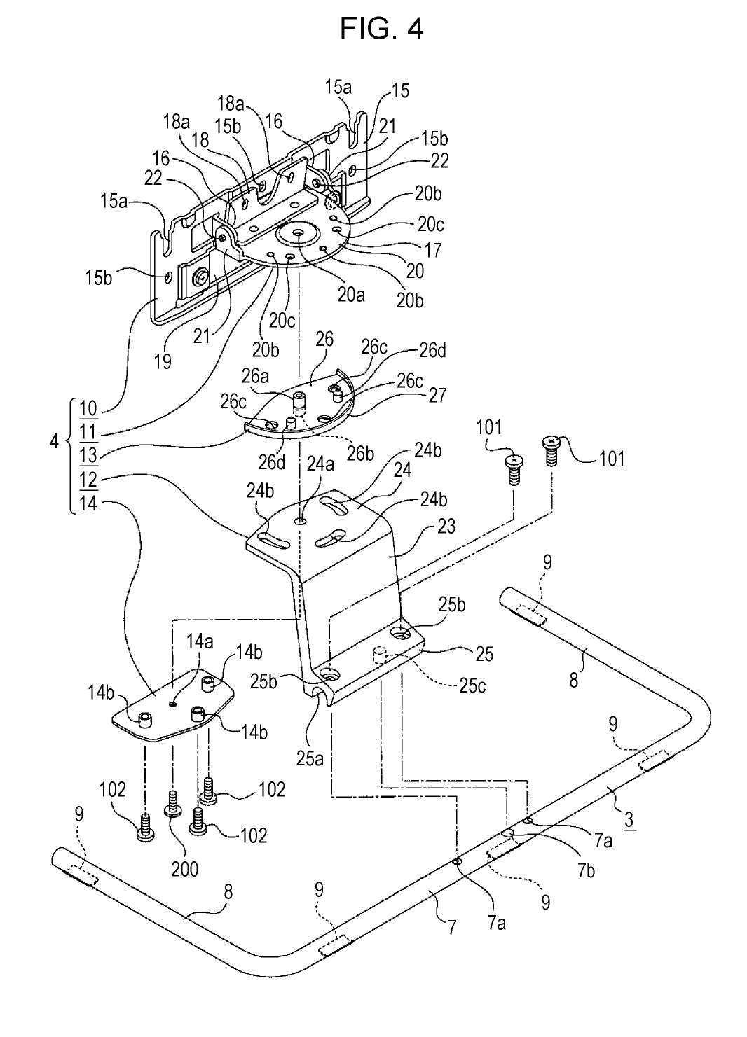

The holding member 3 is formed by, for example, a member which is a round shaft formed of metal being bent into a predetermined shape (refer to FIGS. 3 and 4). The holding member 3 is formed from a base portion 7 which extends left and right and side portions 8 and 8 which respectively extend forward from both left and right edge portions of the base portion 7.

In the center portion of the base portion 7 in the left and right direction, as shown in FIG. 4, screw holes 7a and 7a which are opened upward are formed so as to be separated left and right, and between the screw holes 7a and 7a, a positioning hole 7b which opens upward is formed.

In a predetermined position in the lower surface of the holding member 3, for example, contact sheets 9, 9, . . . which are formed from a rubber material or the like are attached. Slipping or rattling of the holding member 3 with regard to the placement surface 100 is prevented by the contact sheets 9, 9, . . . .

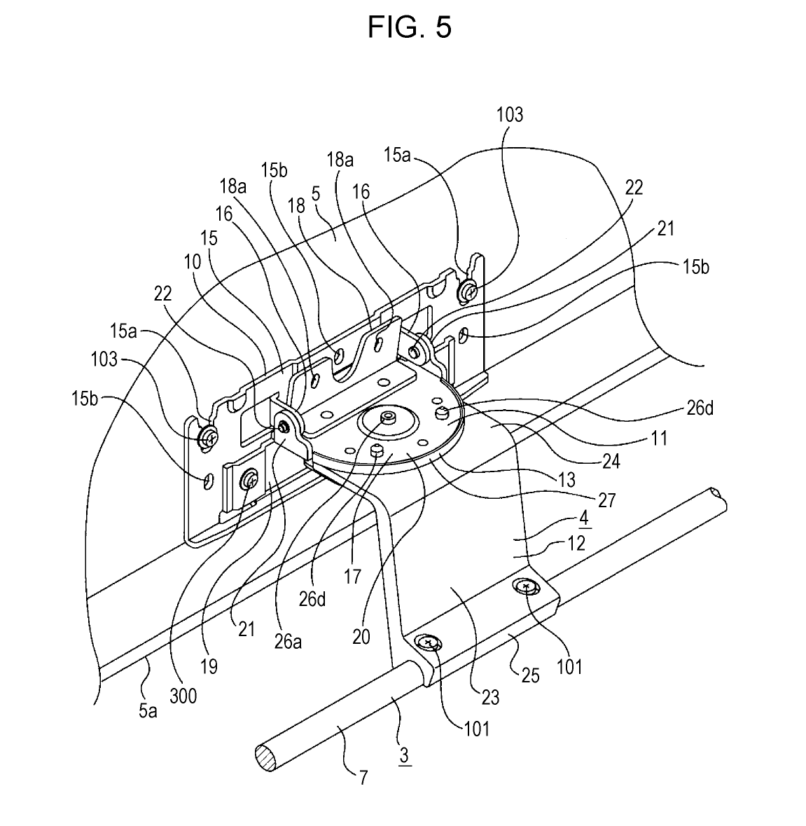

The stand 4 is formed from a base plate 10, an angle changing base 11, a support base 12, a sliding plate 13 and a rotation plate 14 (refer to FIGS. 3 to 5).

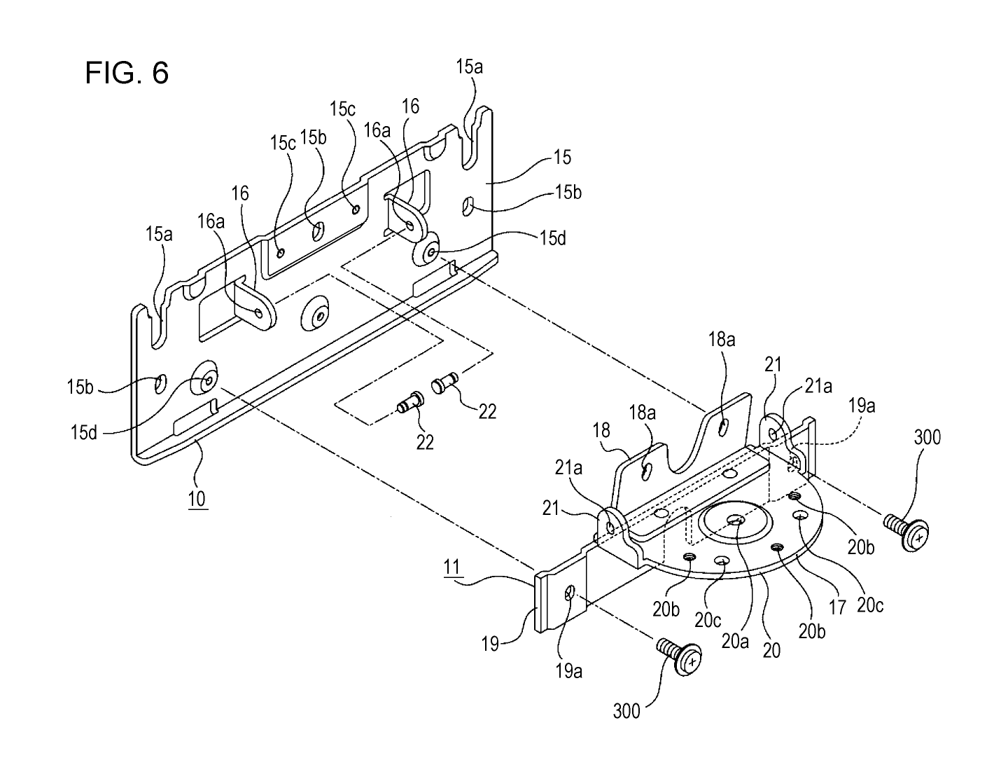

As shown in FIG. 6, the base plate 10 is formed by an attachment portion 15, which is formed with a lateral length shape which substantially faces in a front and back direction, and contact protrusion portions 16 and 16, which protrude back from the attachment portion 15, being integrally formed.

The attachment portion 15 is provided as a lower-side attachment portion where the attaching portion 5b of the display 2 is attached, and in the attachment portion 15, screw insertion notches 15a and 15a, which penetrate front and back and are opened upward, and screw insertion holes 15b, 15b, and 15b which penetrate front and back are formed. In the attachment portion 15, upper-side spiral holes 15c and 15c which respectively penetrate front and back are formed at positions toward the upper edge so as to be separated left and right and lower-side spiral holes 15d and 15d which penetrate front and back are formed at a position toward the lower edge so as to be separated left and right.

The connecting protrusion portions 16 and 16 are positioned so as to be separated left and right and have support holes 16a and 16a which respectively penetrate left and right.

The angle changing base 11 is formed from a connecting surface portion 17, a first joining portion 18, and a second joining portion 19.

The connecting surface portion 17 is formed from a supported surface portion 20 which is formed in a plate shape facing the up and down direction and connecting portions 21 and 21 which respectively protrude upward from both left and right edges of a front edge portion of the supported surface portion 20.

A boss insertion hole 20a which penetrates up and down is formed in the substantially center portion of the supported surface portion 20, and spiral holes 20b, 20b, and 20b which penetrate up and down are formed in a position in the vicinity of the boss insertion hole 20a so as to be separated in a circumferential direction. The supported surface portion 20 is formed so that the outer circumference edge excluding the front edge is an arc shape. In the supported surface portion 20, positioning holes 20c and 20c which respectively penetrate up and down are formed between the spiral holes 20b, 20b, and 20b.

Insertion holes 21a and 21a which respectively penetrate left and right are formed in the connecting portions 21 and 21. The insertion holes 21a and 21a are formed in an elongated shape which is long up and down.

The first joining portion 18 and the second joining portion 19 are formed so that orientations in a tilt direction, that is, a rotation direction where a shaft which extends left and right is a supporting point, are different.

The first joining portion 18 has first joining holes 18a and 18a which protrude substantially upward from a front edge portion of the supported surface portion 20 and penetrate front and back. The first joining holes 18a and 18a are positioned so as to be separated left and right.

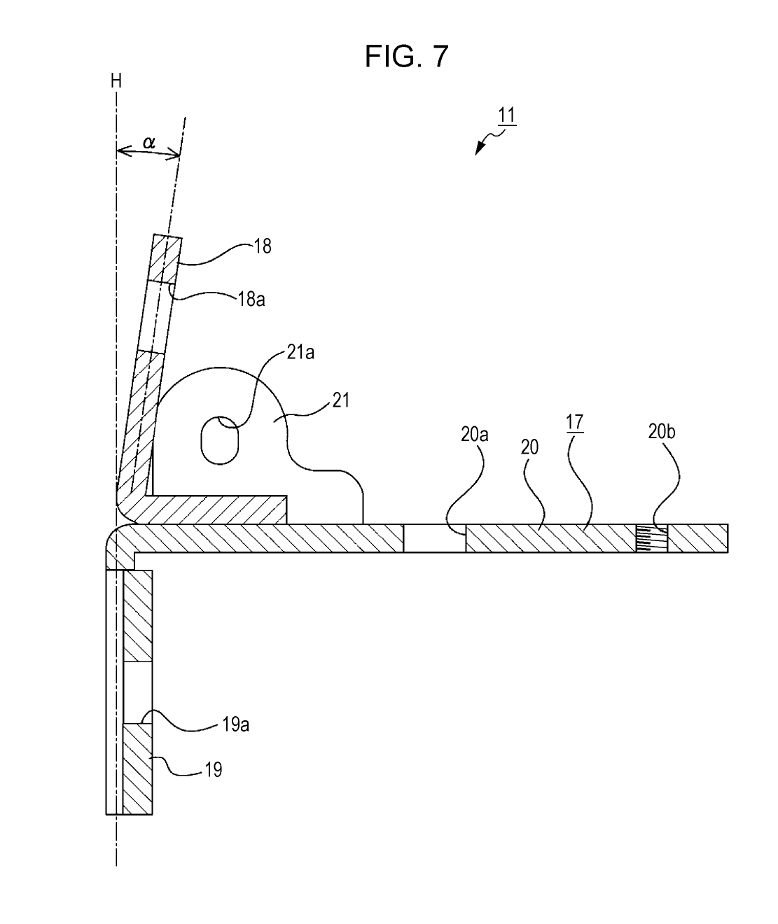

The first joining portion 18 is in a state of being inclined in a direction where there is a change in position slightly to the rear in the vertical direction in a state where the supported surface portion 20 faces the up and down direction (refer to FIG. 7). That is, in a state where the supported surface portion 20 faces the up and down direction, the first joining portion 18 is in a state of being inclined at an angle α to the rear in regard to a vertical direction H. The angle α is set at, for example, 6°.

The second joining portion 19 is in a state of protruding downward from a front edge portion of the supported surface portion 20 and where both left and right edge portions respectively protrude left and right more than the supported surface portion 20 (refer to FIG. 6). Second joining holes 19a and 19a which penetrate front and back are formed in the second joining portion 19 and the second joining holes 19a and 19a are respectively positioned at both left and right edge portions of the second joining portion 19.

The base plate 10 is connected to the angle changing base 11 via rotation shafts 22 and 22 so as to be able to rotate (refer to FIGS. 4 to 6). The rotation shafts 22 and 22 are respectively inserted in the support holes 16a and 16a, which are formed in the connecting protrusion portions 16 and 16 of the base plate 10, and the insertion holes 21a and 21a, which are formed in the connecting portions 21 and 21 of the angle changing base 11, and function as a rotation supporting point of the base plate 10 with regard to the angle changing base 11.

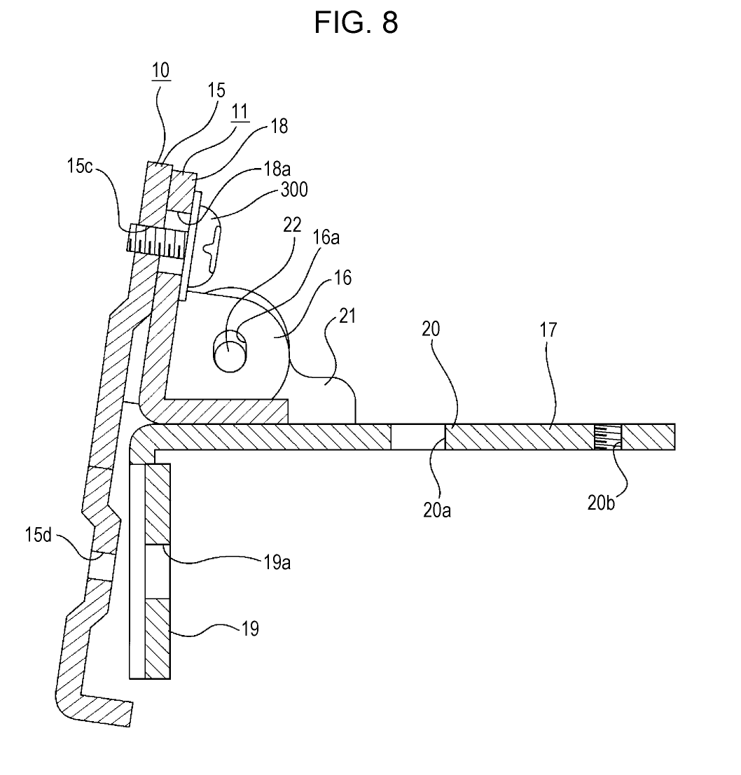

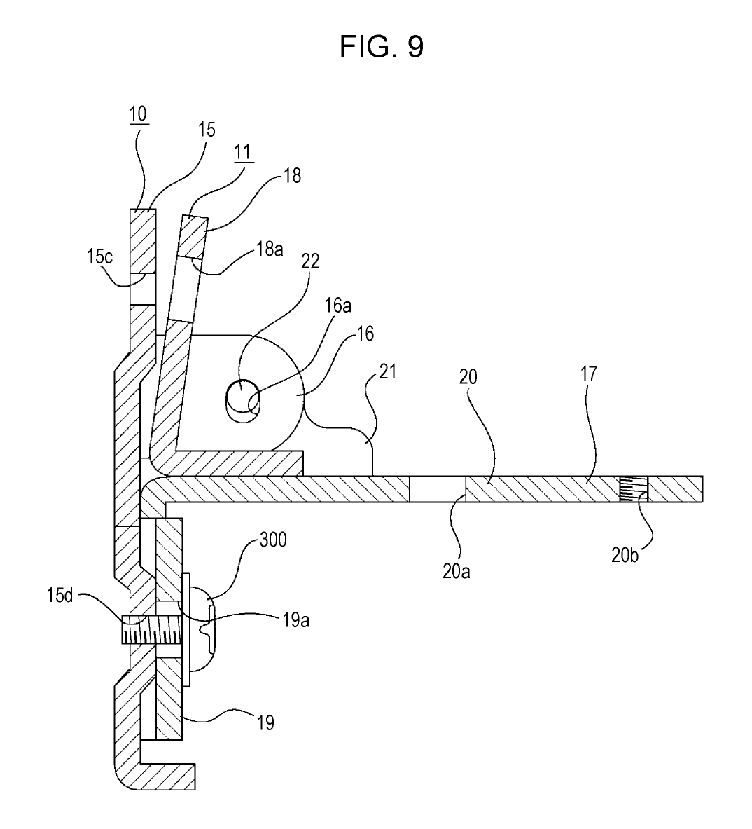

In a state where the base plate 10 is connected to the angle changing base 11 so as to be able to rotate, the base plate 10 is able to rotate between a first rotation position (refer to FIG. 8), where an upper edge portion of the rear surface of the attachment portion 15 comes into contact with the front surface of the first joining portion 18 of the angle changing base 11, and a second rotation position (refer to FIG. 9), where a lower edge portion of the rear surface of the attachment portion 15 comes into contact with the front surface of the second joining portion 19 of the angle changing base 11.

During rotation of the base plate 10 with regard to the angle changing base 11, since the insertion holes 21a and 21a of the connecting portions 21 and 21 are formed in an elongated shape which is long up and down as described above, the rotation shafts 22 and 22 are respectively able to move in the up and down direction in the insertion holes 21a and 21a, and in accordance with the movement of the rotation shafts 22 and 22, the base plate 10 moves in the up and down direction with regard to the angle changing base 11.

The support base 12 is formed so that an erect portion 23 which extends up and down, a support surface portion 24 which extends forward from an upper edge portion of the erect portion 23, and a lower-side attachment portion 25 which is provided at a lower edge portion of the erect portion is integrally formed using a metal material such as aluminum (refer to FIGS. 3 and 4).

A penetration hole 24a which penetrates up and down and boss penetration holes 24b, 24b, and 24b which are positioned in the vicinity of the penetration hole 24a are formed in the support surface 24 so as to be separated in the circumference direction. The boss penetration holes 24b, 24b, and 24b are formed in arc shapes which extend in the circumference position with the penetration hole 24a as a center.

An attachment groove 25a which opens downward and extends left and right is formed in the lower-side attachment portion 25. Screw holes 25b and 25b which penetrate up and down are formed in the lower-side attachment portion 25 so as to be separated left and right, and the lower sides of the openings of the respective screw holes 25b and 25b communicate with the attachment groove 25a. A positioning pin 25c which protrudes downward is provided in the lower-side attachment portion 25 and the positioning pin 25c is positioned in the attachment groove 25a.

In the support base 12, the base portion 7 is inserted in the attachment groove 25a and the positioning pin 25c is inserted in the positioning hole 7b, and the lower-side attachment portion 25 is attached to the holding member 3 by first attaching screws 101 and 101 being respectively inserted in the screw holes 25b and 25b and screwed into the screw holes 7a and 7a. At this time, by inserting the positioning pin 25c is inserted in the positioning hole 7b, the positioning of the support base 12 in the front and back and left and right is performed with regard to the holding member 3, and the support base 12 is attached to the holding member in a state where the erect portion 23 is substantially vertical in the center portion of the base portion 7 in the left and right direction and in a state where the support surface portion 24 is horizontal.

The sliding plate 13 is supported to be able to rotate freely in the horizontal direction on the upper surface of the support surface 24 in the support base 12. The sliding plate 13 is formed from a resin material which has excellent slidability and is formed from a sliding surface portion 26 with a plate shape facing in the up and down direction and a circumference surface portion 27 which protrudes upward from the circumference edge excluding the front side of the sliding surface portion 26. The circumference surface portion 27 is formed in an arc shape.

An upper-side boss portion 26a with a cylindrical shape which protrudes upward and a lower-side boss portion 26b with a cylindrical shape which protrudes downward are provided in the sliding surface portion 26, and the upper-side boss portion 26a and the lower-side boss portion 26b is provided on the same shaft. Boss insertion holes 26c, 26c, and 26c which are positioned in the vicinity of the upper-side boss portion 26a are formed in the sliding surface portion 26 so as to be separated in the circumferential direction. Positioning shafts 26d and 26d which respectively protrude upward are provided between the boss insertion holes 26c, 26c, and 26c of the sliding surface portion 26.

The sliding plate 13 is supported by the support surface portion 24 to be able to rotate freely with the lower-side boss portion 26b as a support point in a state where the lower-side boss portion 26b is inserted in the penetration hole 24a.

The rotation plate 14 is supported by the lower surface of the support surface portion 24 in the support base so as to be able to rotate freely in the horizontal direction. The rotation plate 14 is formed in a plate shape using a resin material which has excellent slidability. A screw member insertion hole 14a which penetrates up and down is formed in the rotation plate 14. Insertion bosses 14b, 14b, and 14b which are positioned in the vicinity of the screw member insertion hole 14a are provided in the rotation plate 14 so as to be separated in the circumference direction. The insertion bosses 14b, 14b, and 14b are formed in a cylindrical shape and protrude upward.

The rotation plate 14 is supported by the support surface portion 24 so as to be able to rotate freely in the horizontal direction with the screw member insertion hole 14a as a support point in a state where the insertion bosses 14b, 14b, and 14b are respectively inserted in the order of the boss penetration holes 24b, 24b, and 24b of the support surface portion 24 and the boss insertion holes 26c, 26c, and 26c of the sliding plate 13.

The insertion bosses 14b, 14b, and 14b of the rotation plate 14 being respectively inserted in the boss insertion holes 26c, 26c, and 26c of the sliding plate 13, the sliding plate 13 and the rotation plate 14 are joined and rotate integrally in the horizontal direction with regard to the support surface portion 24.

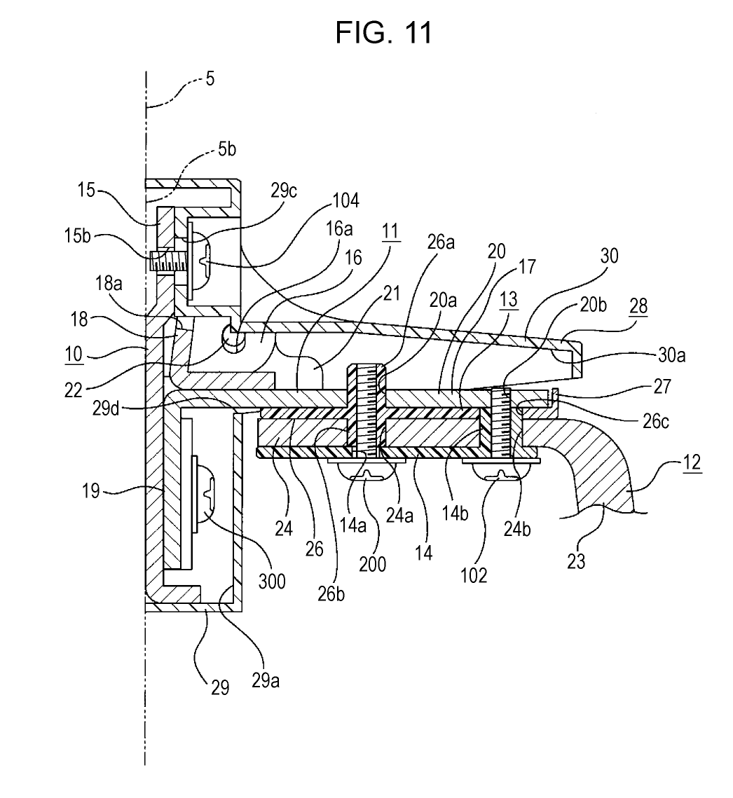

The base plate 10 and the angle changing base 11 are covered using a cover body 28 (refer to FIGS. 3 and 11). The cover body 28 is formed so that a first cover portion 29, which is formed in a rectangular shape with a lateral length, and a second cover portion 30, which protrudes backward from the first cover portion 29, are integrally formed.

A shallow first covering concave portion 29a which opens to the front is formed in the first cover portion 29. Screw fastening holes 29b, 29b, . . . which penetrates front and back and attachment holes 29c, 29c, and 29c which penetrate front and back are formed in the first cover portion 29.

A shallow second covering concave portion 29b which opens downward is formed in the second cover portion 30.

A communication hole 29d is formed in the first cover portion 29 in a portion which is continuous with the second cover portion 30, and due to the communication hole 29d, the first cover concave portion 29a and the second cover concave portion 30a communicate.

The base plate 10 is covered from the rear using the first cover portion 29 due to being accommodated in the first cover concave portion 29a and the angle changing base 11 is inserted from the cover hole 29d and is covered from above using the second cover portion 30 due to being accommodated in the second cover concave portion 30a.

By the base plate 10 and the angle changing base 11 being covered by the cover body 28 in this manner, it is possible to prevent dust from adhering to the base plate 10 and the angle changing base 11.

The supported surface portion 20 of the angle changing base 11 is attached to the sliding plate 13 in a state where the sliding plate 13 and the rotation plate 14 are joined while interposing the support surface section 24 (refer to FIGS. 3, 5, and 11). The attachment of the supported surface portion 20 to the sliding plate 13 is performed by the positioning shafts 26d and 26d being respectively inserted in the positioning holes 20c and 20c from below, the upper-side boss portion 26a being inserted in the boss insertion hole 20a from below, and the second attaching screws 102, 102, and 102 being respectively inserted in the insertion bosses 14b, 14b, and 14b of the rotation plate 14 and screwed into the spiral holes 20b, 20b, and 20b. Accordingly, the sliding plate 13, the rotation plate 14, the angle changing base 11, and the base plate 10 rotate integrally in the horizontal direction with regard to the support surface section 24 of the base portion 12.

In a state where the supported surface section 20 is attached to the sliding plate 13, a screw member 200 is inserted in order through the screw member insertion hole 14a of the rotation plate 14 and the lower-side boss portion 26b of the sliding plate 13 and screwed into the upper-side boss portion 26a of the sliding plate 13. In a state where the supported surface portion 20 is attached to the sliding plate 13, the circumference surface portion 27 is positioned along the outer side of the outer circumference surface of the supported surface portion 20.

The base plate 10 is attached to the display 2 by third attaching screws 103 and 103 being respectively inserted in the screw insertion notches 15a and 15a and screwed into the screw fastening holes 5c and 5c formed in the attaching portion 5b of the housing 5.

In addition, the cover body 28 is attached to the display 2 by fourth attaching screws 104, 104, and 104 being respectively inserted in the attachment holes 29c, 29c, and 29c and screwed into the screw fastening holes 5c, 5c, and 5c which are formed in the attaching portion 5b of the housing 5, and the base plate 10 and the angle changing base 11 are covered by the cover body 28 (refer to FIGS. 3 and 11). At this time, the fourth attaching screws 104, 104, and 104 are screwed into the screw fastening holes 5c, 5c, and 5c in a state of having respectively penetrated the screw insertion holes 15b, 15b, and 15b of the angle changing base 11. Accordingly, the cover body 28 is attached to the display 2 using the fourth attaching screws 104, 104, and 104, and at the same time, the base plate 10 is attached to the display 2 using the fourth attaching screws 104, 104, and 104.

[Operation and the like of Display Device]

In the display device 1 which is configured as described above, it is possible to change the inclination angle of the display in the tilt direction 2 by changing the position of the angle changing base 11 which joins with the base plate 10 in this manner.

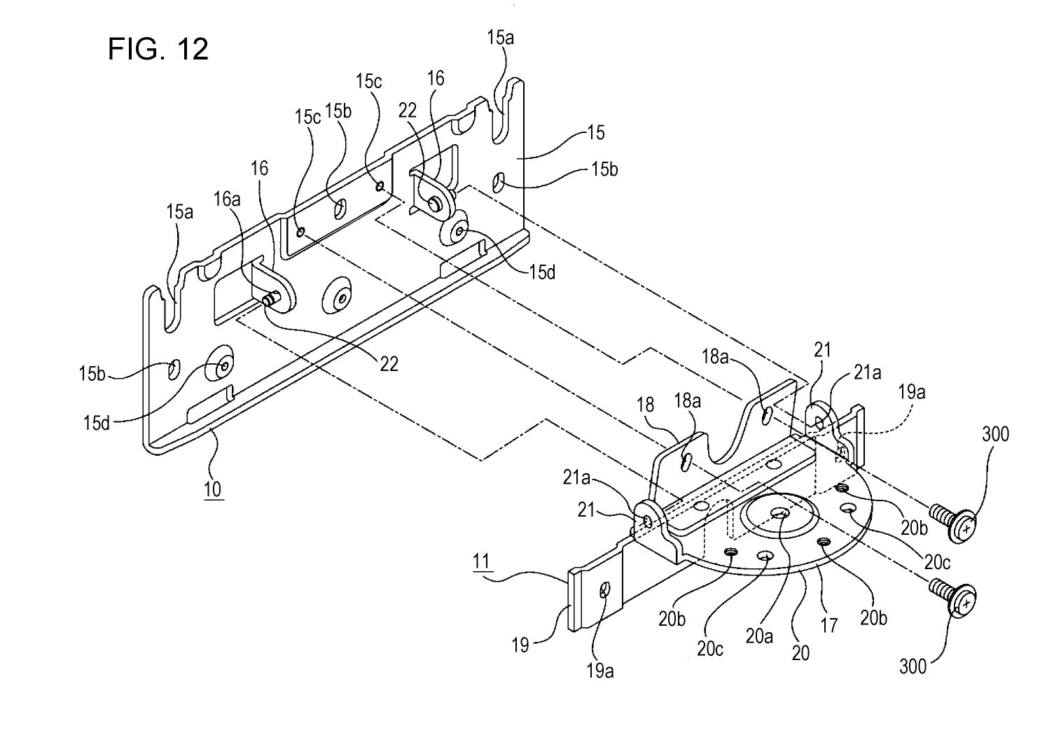

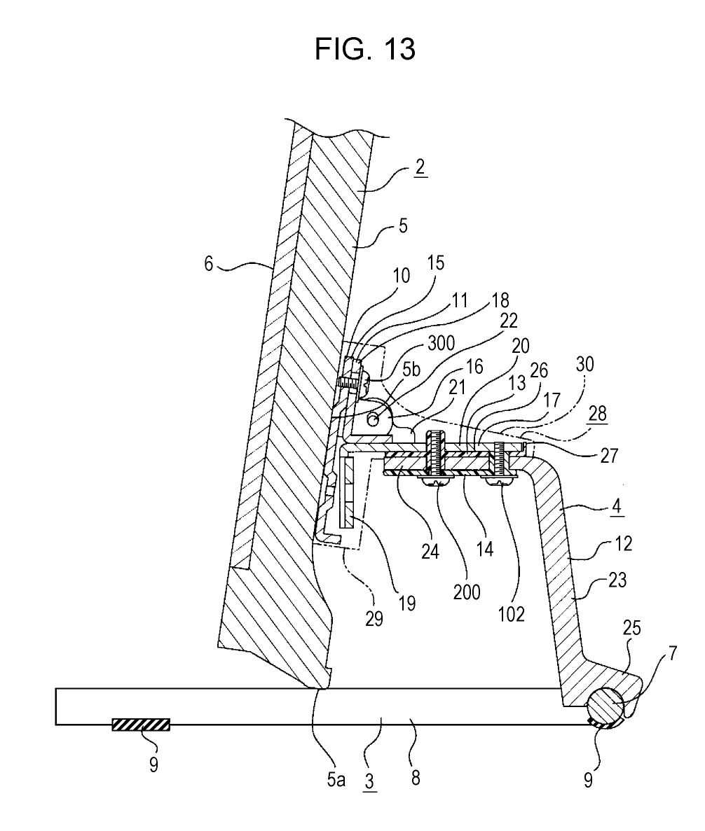

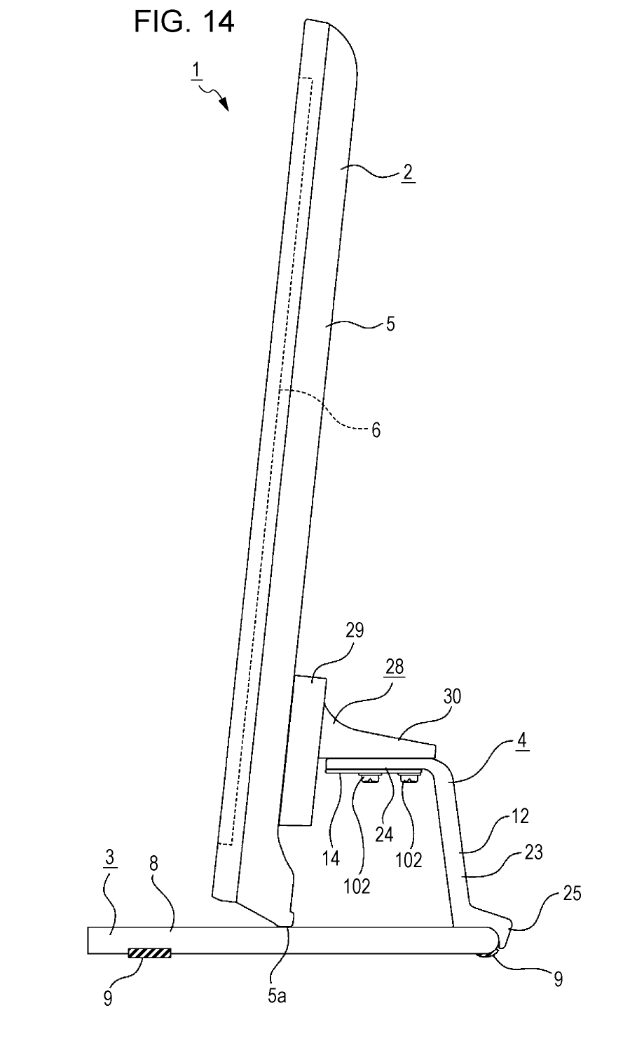

For example, as shown in FIGS. 12 and 13, it is possible to hold the display 2 at a first inclination angle using attachment of the first joining portion 18 to the base plate 10 by changing attaching screws 300 and 300 being respectively inserted in the first joining holes 18a and 18a which are formed in the first joining portion 18 of the angle changing base 11 and screwed into the upper-side spiral holes 15c and 15c of the base plate 10 (refer to FIG. 14). At this time, the base plate 10 is held in a first rotation position. The first inclination angle is an angle where the display surface 6 of the display 2 faces forward and diagonally upward, and is an angle inclined by, for example, 6° in regard to the vertical direction.

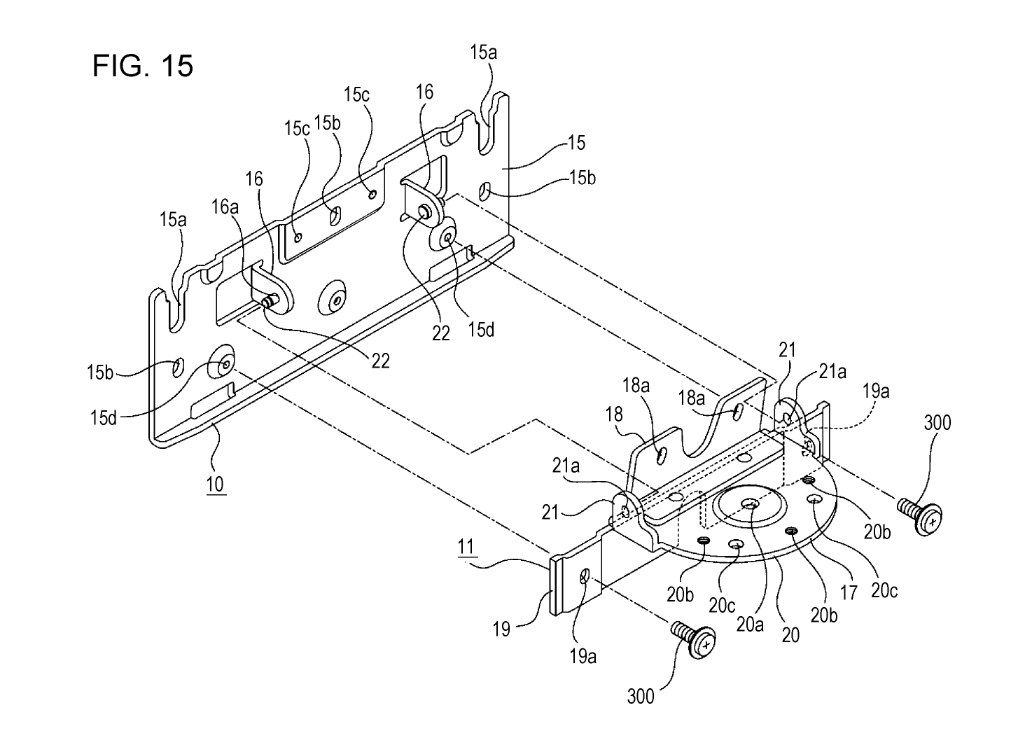

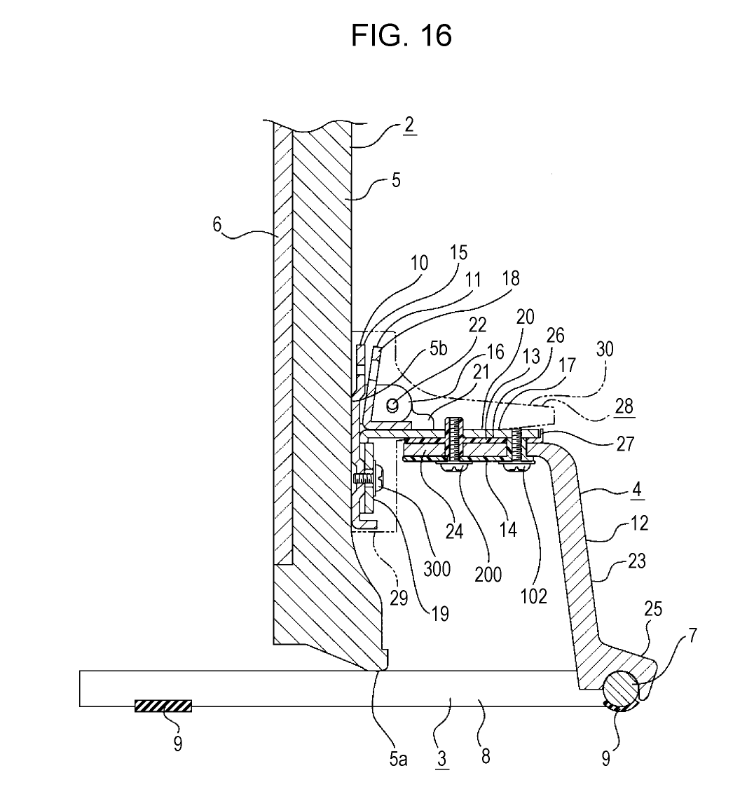

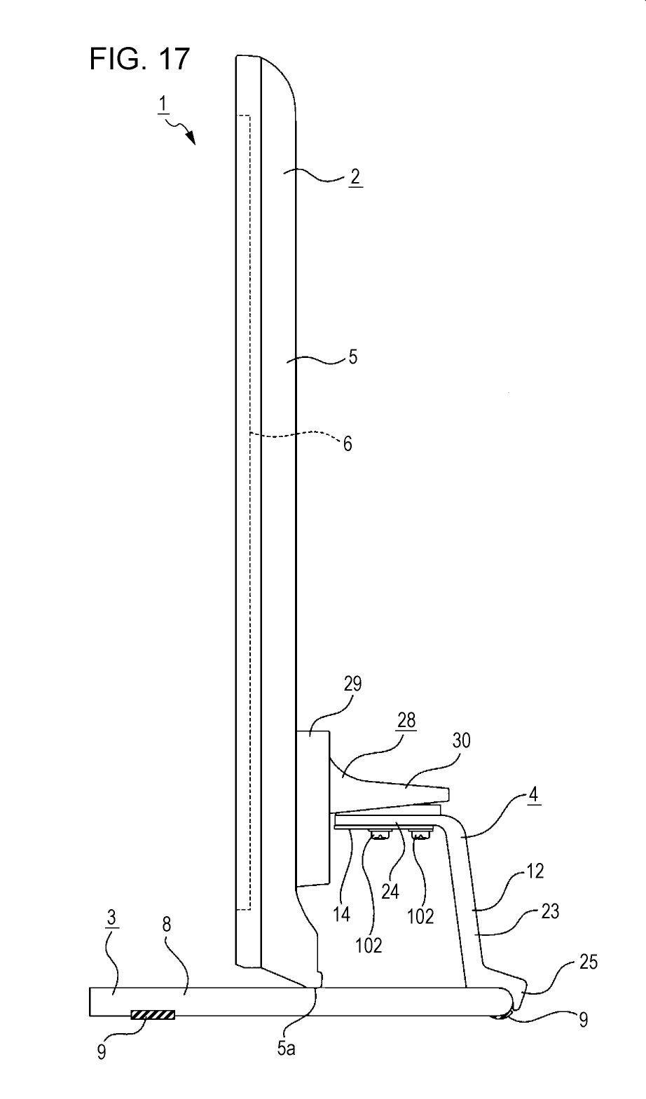

In addition, the joining of the first joining portion 18 with regard to the base plate 10 is released using the changing attaching screws 300 and 300 and the base plate 10 rotates with regard to the angle changing base 11 until a second rotation position with the rotation shafts 22 and 22 as supporting points. In a state where the base plate 10 has rotated until the second rotation position, as shown in FIG. 15 and 16, it is possible to hold the display 2 at an angle where the display surface 6 faces the horizontal direction using attachment of the second joining portion 19 to the base plate 10 by the changing attaching screws 300 and 300 being respectively inserted in the second joining holes 19a and 19a which are formed in the second joining portion 19 of the angle changing base 11 and screwed into the lower-side spiral holes 15d and 15d of the base plate 10 (refer to FIG. 17).

In the display device 1, even in any state where the display 2 is held at the two angles described above, portions on both left and right sides of the contact portion 5a of the display 2 are in a state of respectively coming into contact with the side portions 8 and 8 of the holding member 3 in the front of the lower-side attachment portion 25 of the stand (refer to FIGS. 13, 14, 16, and 17).

As described above, when the inclination angle is changed in the tilt direction of the display 2, since the base plate 10 rotates with regard to the angle changing base 11 with the rotation shafts 22 and 22 as supporting points, the position of the contact portion 5a changes in the up and down direction with regard to the holding member 3. However, in the display device 1, since the insertion holes 21a and 21a of the connecting portions 21 and 21 are formed in an elongated shape which is long up and down as described above, the base plate 10 is able to move in the up and down direction along with the rotation shafts 22 and 22. Accordingly, during rotation of the base plate 10 with regard to the angle changing base 11, the rotation shafts 22 and 22, the base plate 10, and the display 2 become integrated and move in the up and down direction with regard to the angle changing base 11 and the contact portion 5a is in a state of coming into contact with each of the side portions 8 and 8 of the holding member 3 irrespective of the inclination angle of the display 2.

In the display device 1, since the contact portion 5a comes into contact with the holding member 3 irrespective of the inclination angle of the display 2 in the tilt direction as described above, the position of the contact portion 5a, which contacts with the holding member 3, and the lower-side attachment portion 25 of the stand 4 are positioned to be separated back and front and normally function as supporting points which supports the display 2, and it is possible to achieve stability of the holding state of the display 2 irrespective of the inclination angle of the display 2.

In addition, the inclination angle of the display 2 in the tilt direction is changed by selectively joining the first joining portion 18 and the second joining portion 19 of the angle changing base 11 to the base plate 10.

Accordingly, since the inclination angle of the display 2 in the tilt direction is changed only by changing the position of the angle changing base 11 which joins with the base plate 10, it is possible to easily performing the changing of the inclination angle of the display 2.

Here, in the description above, an example was shown where the display 2 is able to be changed to two different inclination angles by two joining portions of the first joining portion 18 and the second joining portion 19 being provided in the angle changing base 11, but it is possible for the display 2 to be able to be changed to three or more different inclination angles by three or more joining portions which have different orientations in the tilt direction being provided in the angle changing base 11.

Furthermore, since the base plate 10 is connected with the angle changing base 11 so as to be able to rotate in the tilt direction, it is possible to easily and promptly perform the changing of the inclination angle of the display 2 without the joining of the base plate 10 and the angle changing base 11 being released when changing the inclination angle of the display in the tilt direction 2.

Here, in the display device 1, since the base plate 10 is connected with the angle changing base 11 so as to be able to rotate in the tilt direction and the screw fastening holes 29b, 29b, . . . are formed in the cover body 28, it is possible to change the position of the angle changing base 11, which joins with the base plate 10, in a state where the base plate 10 and the angle changing base 11 are covered by the cover body 28.

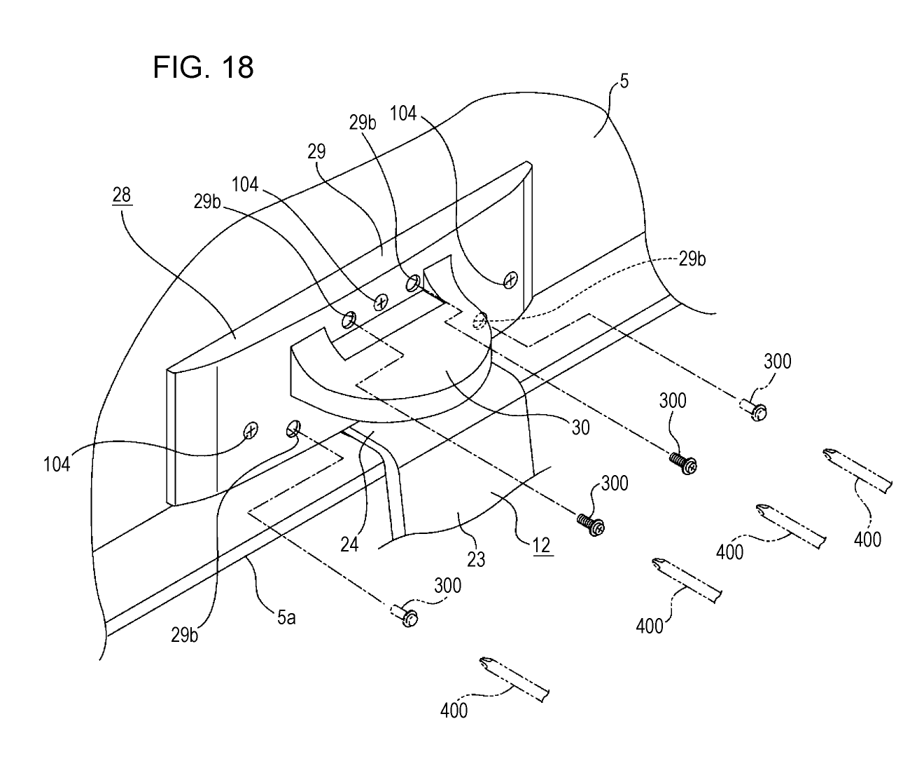

It is possible for the changing of the position of the angle changing base 11, which joins with the base plate 10, in a state where the base plate 10 and the angle changing base 11 are covered by the cover body 28 to be performed by changing attaching screws 400, 400, . . . being inserted or removed with regard to the screw fastening holes 29b, 29b, . . . using a fastening tool 400 such as a screw driver (refer to FIG. 18).

Specifically, the fastening tool 400 is inserted into the screw fastening holes 29b and 29b, the screwing of the changing attaching screws 400, 400, . . . is released with regard to the upper-side spiral holes 15c and 15c or the lower-side spiral holes 15d and 15d of the attachment portion 15, and the changing attaching screws 400 and 400 are removed to the outside of the cover body 28. Next, it is possible to change the position of the angle changing base 11, which joins with the base plate 10, by the fastening tool 400 being inserted into other screw fastening holes 29b and 29b and the screwing of the changing attaching screws 400, 400, . . . with regard to the upper-side spiral holes 15c and 15c or the lower-side spiral holes 15d and 15d of the attachment portion 15.

By changing the position of the angle changing base 11, which joins with the base plate 10, in a state where the base plate 10 and the angle changing base 11 are covered by the cover body 28 in this manner, it is possible to perform the changing of the position of the joining without removing the cover body 28 from the display 2. Accordingly, it is possible to easily and promptly perform the changing of the position of the angle changing base 11 which joins with the base plate 10.

In addition, since the insertion holes 21a and 21a of the connecting portions 21 and 21 are formed in an elongated shape which is long up and down and the base plate 10 moves in the up and down direction along with the rotation shafts 22 and 22 when changing the inclination angle of the display 2, it is possible to make the contact portion 5a of the display 2 reliably contact with the holding member 3 irrespective of the inclination angle of the display 2.

Furthermore, it is possible to achieve stability of the holding state of the display 2 since a member with a shaft shape, which is formed from the base portion 7 which extends left and right and the pair of side portions 8 and 8 which extend forward from both left and right edge portions of the base portion 7, is provided as the holding member 3 and the lower-side attachment portion 25 of the stand 4 is attached to the center portion of the base portion 7 in the left and right direction.

In addition, furthermore, since the contact portion 5a of the display 2 contacts with the holding member 3 in two locations, and since along with the lower-side attachment portion 25 of the stand 4, the display 2 is supported at three locations, it is possible to achieve further stability of the holding state of the display 2.

In addition, since the positions of the contact portion 5a of the display 2, which contacts with the holding member 3, are positioned to be separated in the left and right direction, along with the lower-side attachment portion 25, the display 2 is supported at three locations which formed corners of a triangle and it is possible to achieve further stability of the holding state of the display 2.

Additionally, since the inclination angle of the display 2 in the tilt direction is set as 0° where the display surface 6 faces the front or another angle, for example, 6° where the display surface 6 faces upward of the front, it is possible to select and view at an angle where visibility of an image which is displayed on the display surface 6 is high.

Here, the inclination angles of the display 2 in the tilt direction are not limited to 0° and 6° but are able to be set to arbitrary angles.

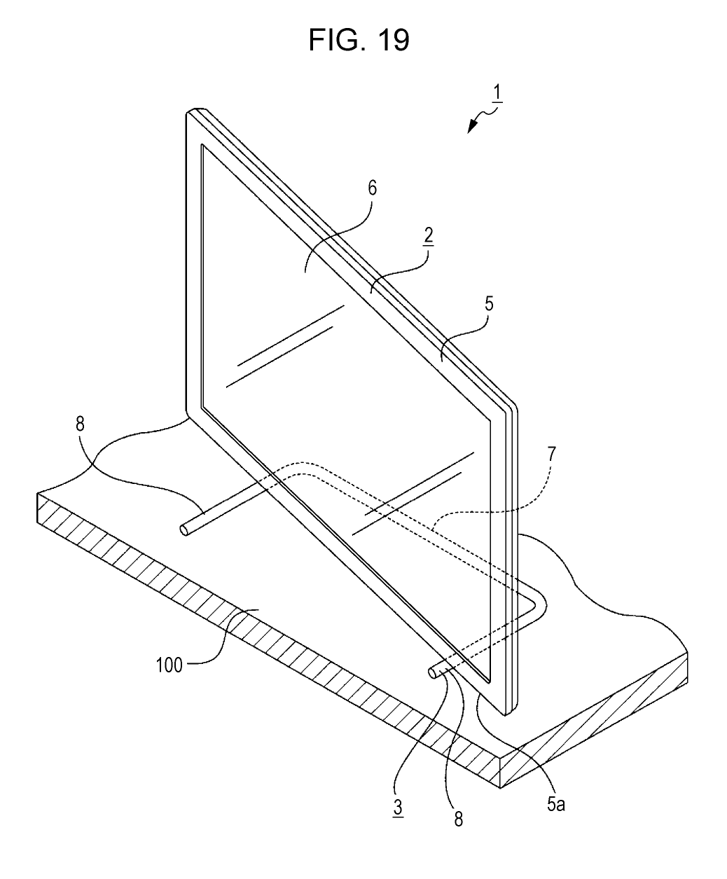

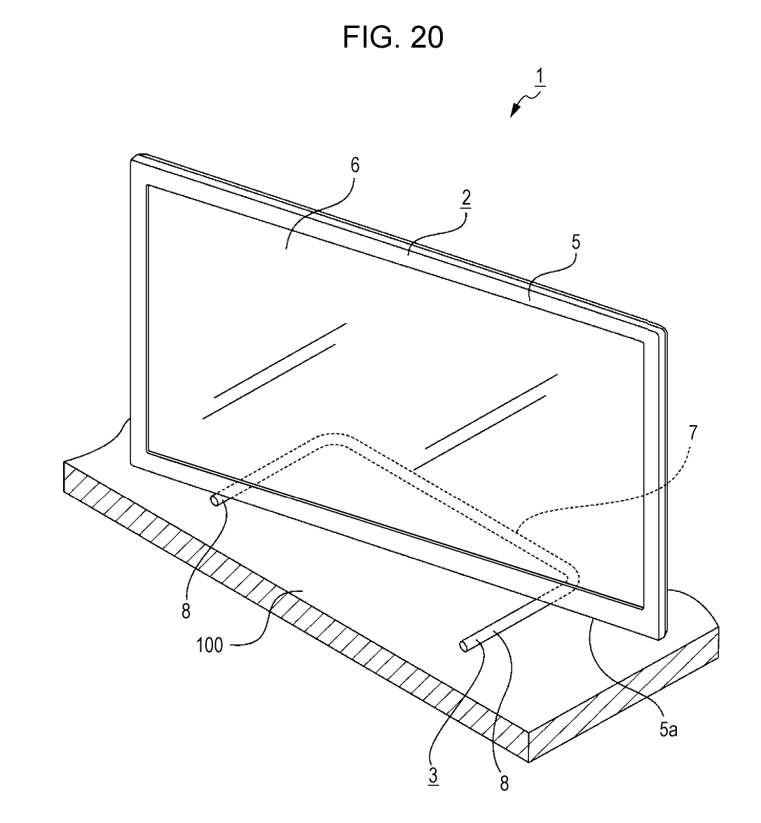

In the display device 1, the sliding plate 13, the rotation plate 14, the angle changing base 11, and the base plate 10 are integrated and are able to rotate in the horizontal direction in regard to the support surface portion of the support base 12. Accordingly, when the sliding plate 13, the rotation plate 14, the angle changing base 11, and the base plate 10 rotate, the display 2 which is attached to the base plate 10 is also rotated in the horizontal direction and it is possible to change the orientation of the display surface 6 in the horizontal direction (refer to FIGS. 19 and 20).

It is possible to perform the rotation of the display 2 in the horizontal direction between a position, where the insertion bosses 14b, 14b, and 14b of the rotation plate 14 respectively contact one edge in a length direction of the boss insertion holes 24b, 24b, and 24b which are formed in the support surface portion 24 of the support base 12 (refer to FIG. 19), and a position, where the insertion bosses 14b, 14b, and 14b respectively contact another edge in the length direction of the boss insertion holes 24b, 24b, and 24b (refer to FIG. 20).

Since the display 2 is able to be rotated in the horizontal direction in this manner, it is possible to select and view at an angle where visibility of an image which is displayed on the display surface 6 is high.

In addition, since the angle changing base 11 is supported by the support base 12 so as to rotate freely in the horizontal direction, the rotation in the tilt direction (changing of the inclination angle) and the rotation in the horizontal direction of the display 2 are performed by the angle changing base 11 which is the same part, and it is possible to achieve a reduction in the number of parts and a simplified structure.

Furthermore, the sliding plate 13, which is formed between the angle changing base 11 and the support base 12 from a resin material, is disposed, and the angle changing base 11 and the sliding plate 13 are integrated and rotate with regard to the support surface portion 24 of the support base 12 when the display 2 is rotated in the horizontal direction.

Accordingly, since the sliding plate 13 which is formed from the resin material slides with the support surface portion 24, it is possible to secure excellent slidability of the sliding plate 13 with regard to the support surface portion 24 and to rotate the display 2 smoothly in the horizontal direction.

Furthermore, in addition, the rotating plate 14, which is disposed at a side opposite to the angle changing base 11 so the support surface portion 24 of the support base 12 is interposed, is provided and the angle changing base 11 and the rotating plate 14 are joined using one screw member 200 at a rotation supporting point while interposing the support surface portion 24.

Accordingly, since a rotating mechanism is configured which rotates the display 2 in the horizontal direction by the angle changing base 11 and the rotating plate being joined using the screw member 200 at a rotation supporting point, it is possible to achieve a reduction in the number of parts and a simplified configuration using the rotation mechanism.

Additionally, the sliding plate 13, which is disposed between the angle changing base 11 and the support surface portion 24, and the rotating plate 14, which is disposed on a side opposite to the sliding plate 13 so that the support surface portion 24 is interposed, are both formed from a resin material and are integrated to rotate together. Accordingly, it is possible to secure excellent slidability of the sliding plate 13 and the rotation plate 14 with regard to the support surface portion 24 and to rotate the display 2 more smoothly in the horizontal direction.

The specific shapes and configurations of each of the portions shown in the embodiment described above show only one specific example when the disclosure is applied, and due to this, the technical scope of the disclosure is not to be interpreted as limited.

The present disclosure contains subject matter related to that disclosed in Japanese Priority Patent Application JP 2010-270785 filed in the Japan Patent Office on Dec. 3, 2010, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display device comprising:
a display which has a display surface which displays an image and where a lower edge portion is provided as a contact portion;
a holding member which is placed on a placement surface, contacts the contact portion of the display from above, and holds the display; and
a stand where an upper edge portion is provided as a upper-side attachment portion which is attached to the display and a lower edge portion is provided as a lower-side attachment portion which is attached to the holding member,
wherein it is possible to change the inclination angle of the display in the tilt direction with regard to the stand to a plurality of angles which are different and a position of the contact portion of the display, which contacts with the holding member, and the lower-side attachment portion of the stand are positioned so as to be separated back and front.

2. The display device according to claim 1,
wherein a base plate which has the upper-side attachment portion, a support base which has the lower-side attachment portion, and an angle changing base which is connected to the base plate and the support base are provided in the stand,
a plurality of types of joining portions where the orientations in the tilt direction are different is provided in the angle changing base, and
the inclination angle of the display in the tilt direction is changed by the plurality of joining portions being selectively joined with the base plate.

3. The display device according to claim 2,
wherein a first joining portion and a second joining portion are provided as the joining portions.

4. The display device according to claim 2,
wherein the base plate is connected to the angle changing base so as to be able to rotate in the tilt direction.

5. The display device according to claim 4,
wherein a connecting protrusion portion which has a support hole is provided in the base plate,
a connecting portion which has an insertion hole is provided in the angle changing base,
the base plate is connected to the angle changing base so as to be able to rotate in the tilt direction by a rotation shaft which extends in a horizontal direction being inserted in the support hole and the insertion hole,
the insertion hole is formed in an elongated shape which extends up and down, and
a position with regard to the insertion hole of the rotation shaft is changed in the up and down direction and the base plate and the display are integrated and move in the up and down direction when the types of the joining portions which are joined to the base plate are changed.

6. The display device according to claim 1,
wherein a member with a shaft shape, which is formed from a base portion which extends left and right and a pair of side portions which respectively extend forward from both left and right edge portions of the base portion, is provided as the holding member, and
the lower-side attachment portion of the stand is attached to the center portion of the base portion in the left and right direction.

7. The display device according to claim 1,
wherein the contact portion of the display contacts with the holding member in two locations.

8. The display device according to claim 7,
wherein the positions of the contact portion of the display, which contacts with the holding member, is positioned so as to be separated in the left and right direction.

9. The display device according to claim 1,
wherein the inclination angle of the display in the tilt direction is set as 0° where the display surface faces the front or another angle where the display surface faces upward of the front.

10. The display device according to claim 1,
wherein the display is made to be able to rotate in the horizontal direction.

11. The display device according to claim 10,
wherein the angle changing base is supported by a support base so as to rotate freely in the horizontal direction.

12. The display device according to claim 11,
wherein a sliding plate, which is formed between the angle changing base and the support base from a resin material, is disposed, and
the angle changing base and the sliding plate are integrated and rotate with regard to the support base when the display is rotated in the horizontal direction.

13. The display device according to claim 11,
wherein a rotating plate, which is disposed in a state of being in contact with the support base at a side opposite to the angle changing base so the support base is interposed, is provided, and
the angle changing base and the rotating plate are joined using a screw member at a rotation supporting point while interposing the support base.

14. The display device according to claim 13,
wherein a sliding plate, which is formed between the angle changing base and the support base from a resin material, is disposed,
the rotating plate is formed from a resin material, and
the angle changing base, the sliding plate, and the rotating plate are integrated and rotate with regard to the support base when the display is rotated in the horizontal direction.

15. The display device according to claim 2,
wherein a cover body, which covers the base plate and the angle changing base, is provided.

16. The display device according to claim 4,
wherein the plurality of joining portions are selectively joined up with the base plate using a changing attaching screw,
a cover body, which covers the base plate and the angle changing base, is provided, and
a screw fastening hole is formed so that it is possible for the changing attaching screw to be inserted in or removed from the cover body.
